(19) United States
(12) Patent Application Publication
(10) Pub. No.: US 2025/0149101 A1
(43) Pub. Date: May 8, 2025

(54) VOLTAGE REGULATION FOR MEMORY ARRAY TEST PROCEDURES

(71) Applicant: Micron Technology, Inc., Boise, ID (US)

(72) Inventor: Anjana Karthik Gudipati, Munich (DE)

(21) Appl. No.: 18/937,401

(22) Filed: Nov. 5, 2024

Related U.S. Application Data
(60) Provisional application No. 63/547,496, filed on Nov. 6, 2023.

(51) Int. Cl. G11C 17/18; G11C 17/16; G11C 29/02

(52) U.S. Cl. CPC G11C 17/18; G11C 17/16; G11C 29/021

(57) ABSTRACT

Methods, systems, and devices for voltage regulation for memory array test procedures are described. A system may utilize multiple voltage regulators to concurrently activate sets of antifuses and to compensate for voltage drops across the antifuses. Each voltage regulator may be associated with a respective region of memory cells. The memory system may apply an activation voltage to antifuse circuitry of a memory array. Respective voltage regulators for each region of memory cells may maintain the activation voltage across respective sets of antifuses of the antifuse circuitry, such that the activation voltage exceeds a respective threshold for each antifuse. Each antifuse of the respective sets of antifuses may be activated based on maintain the activation voltage using the multiple voltage regulators. The set of antifuses may transition from a resistive state to a conductive state based on activating the set of antifuses.

### CROSS REFERENCE

The present Application for Patent claims priority to U.S. Patent Application No. 63/547,496 by Anjana Karthik Gudipati, entitled “VOLTAGE REGULATION FOR MEMORY ARRAY TEST PROCEDURES,” filed Nov. 6, 2023, which is assigned to the assignee hereof, and which is expressly incorporated by reference in its entirety herein.

### TECHNICAL FIELD

The following relates to one or more systems for memory, including voltage regulation for memory array test procedures for memory systems.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports voltage regulation for memory array test procedures in accordance with examples as disclosed herein.

FIG. 2 shows an example of an architecture that supports voltage regulation for memory array test procedures in accordance with examples as disclosed herein.

FIG. 3 shows an example of a system that supports voltage regulation for memory array test procedures in accordance with examples as disclosed herein.

FIG. 4 shows a block diagram of a memory system that supports voltage regulation for memory array test procedures in accordance with examples as disclosed herein.

FIG. 5 shows a flowchart illustrating a method or methods that support voltage regulation for memory array test procedures in accordance with examples as disclosed herein.

### DETAILED DESCRIPTION

Some systems may include memory arrays that include antifuse circuitry. In some cases, a system may be configured to activate (e.g., blow) respective antifuses to alter internal circuitry (e.g., and functionality) of the system. For instance, one or more antifuses may be activated to perform repair procedures for the system (e.g., row repair, column repair), to activate test modes (e.g., activation of different test voltage levels), and/or to improve or calibrate a performance of the system, among other examples. Antifuses may be activated by applying a voltage (e.g., an activation voltage) across the antifuses, which may cause the antifuses to transition from a resistive state to a conductive state. Some antifuse activation procedures may include sequential activation of multiple antifuses (e.g., one antifuse at a time), but such sequential activation may be relatively slow and may not be feasible for some manufacturing procedures (e.g., high volume manufacturing). In some cases, concurrently attempting to activate multiple antifuses may reduce a duration associated with the antifuse activation but may also result in a reduced voltage applied to each antifuse such that at least some of the antifuses may not be activated. Further, in some cases, increasing the activation voltage to compensate for the reduced voltage may cause damage to a device, may inadvertently activate other antifuses, or may not be feasible based on device constraints (e.g., voltage constraints, temperature constraints). Accordingly, techniques to concurrently activate an increased quantity of antifuses while mitigating such adverse effects may be beneficial to improve efficiency of manufacturing and operating memory devices.

In accordance with techniques described herein, a memory system may utilize one or more voltage regulators to enhance parallel activation of antifuses. A voltage regulator may be a device (e.g., a capacitor, a voltage generator, or other component) that maintains (e.g., regulates) an applied voltage level across one or more components of the memory system. The voltage regulators may compensate for a reduced voltage and may concurrently activate multiple antifuses (e.g., more antifuses than can be activated without the voltage regulators). In some examples, each voltage regulator may be associated with a respective region of memory cells (e.g., a voltage regulator may be local to a respective region). For example, sets of antifuses may be associated with respective regions of memory cells and may be concurrently activated based on utilizing respective voltage regulators associated with each of the respective regions of memory cells. The voltage regulators may enable a device to maintain an activation voltage across an increased quantity of antifuses (e.g., without increasing the activation voltage, without exceeding device constraints), which may reduce durations (e.g., test times) and activation attempts associated with antifuse activation procedures. Thus, the techniques described herein provide for improved efficiency of manufacturing procedures and improved reliability and accuracy of antifuse activation procedures, among other benefits.

In addition to applicability in memory systems as described herein, techniques for voltage regulation for memory array test procedures may be generally implemented to improve the sustainability of various electronic devices and systems. As the use of electronic devices has become even more widespread, the quantity of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by improving efficiency and efficacy in the manufacturing of electronic devices. For example, using voltage regulators to perform enhanced parallel antifuse activation during production processes may improve efficiency of high volume manufacturing, improve accuracy and reliability of test procedures, decrease production processes, and result in lowered production emissions, among other benefits.

Features of the disclosure are illustrated and described in the context of systems and architectures. Features of the disclosure are further illustrated and described in the context of block diagrams and flowcharts.

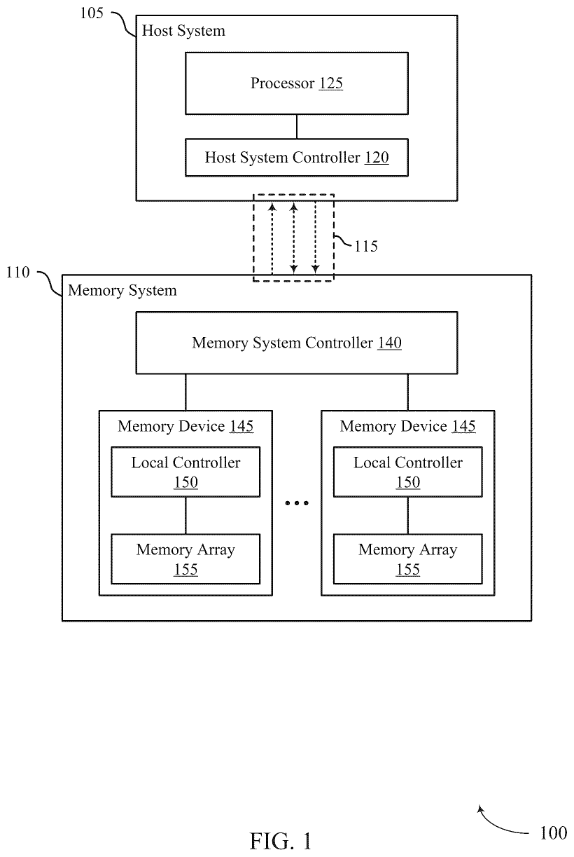

FIG. 1 illustrates an example of a system 100 that supports voltage regulation for memory array test procedures in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not- and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

Some memory systems 110 (e.g., or host systems 105) may include antifuse circuitry, which may be used to modify circuitry associated with the memory system 110 (e.g., as part of an evaluation procedure or a test procedure during manufacture of the device, operation of the device, or both). In some cases, a controller (e.g., a host system controller 120, a memory system controller 140, a local controller 150, an external controller, or any combination thereof) or some other component of the system 100 may activate an antifuse by applying an activation voltage across the antifuse. However, some antifuse activation techniques may not be adequate for some test procedures (e.g., associated with high volume manufacturing) at least because the test procedures may be associated with relatively long durations (e.g., sequential antifuse blowing) or with voltage drop effects (e.g., based on parallel application of the activation voltage to multiple antifuses). Thus, techniques to reduce a duration associated with antifuse activation and to compensate for voltage drop effects (e.g., as part of a test phase of manufacturing) may be beneficial.

In accordance with techniques described herein, a system 100 may utilize multiple voltage regulators (e.g., voltage generators, capacitors) to concurrently activate multiple antifuses (e.g., multiple sets of three or more antifuses). In some examples, utilizing the multiple voltage regulators may decrease antifuse activation time (e.g., by concurrently and/or simultaneously blowing multiple sets of antifuses) and compensate for voltage drops (e.g., across a set of antifuses). For example, multiple voltage regulators may be associated with respective regions of a memory array 155 and may concurrently and/or simultaneously activate multiple sets of antifuses associated with the respective regions of the memory array 155. Thus, a system 100 may be manufactured with increased efficiency and with improved reliability, among other benefits.

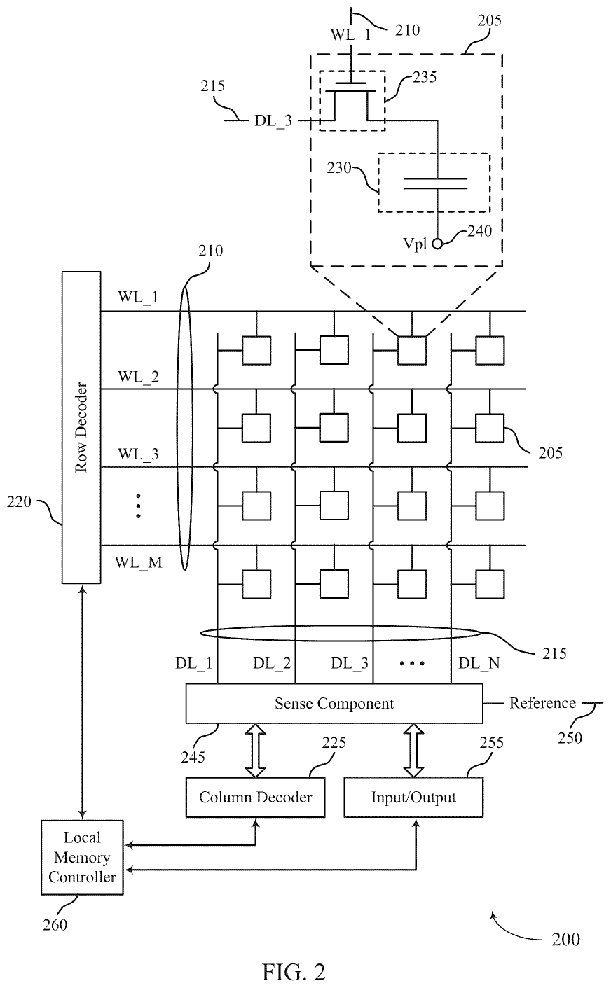

FIG. 2 illustrates an example of an architecture 200 (e.g., a memory architecture) that supports voltage regulation for memory array test procedures in accordance with examples as disclosed herein. The architecture 200 may be implemented in a memory system 110 or one or more components thereof (e.g., memory device 145). Aspects of the architecture 200 may be referred to as or implemented in a semiconductor component, such as a memory die.

The architecture 200 includes memory cells 205 that are programmable to store information. In some examples, a memory cell 205 may be operable to store one bit of information at a time (e.g., a logic 0 or a logic 1). In some examples, a memory cell 205 (e.g., a multi-level memory cell) may be operable to store more than one bit of information at a time (e.g., a logic 00, logic 01, logic 10, a logic 11). Memory cells 205 may be arranged in an array, such as in a memory array 155.

In the example of architecture 200, a memory cell 205 may include a storage component, such as capacitor 230, and a selection component 235 (e.g., a cell selection component, a transistor). A capacitor 230 may be a dielectric capacitor or a ferroelectric capacitor. A node of the capacitor 230 may be coupled with a voltage source 240, which may be a cell plate reference voltage, such as Vp1, or may be a ground voltage, such as Vss. A charge stored by a memory cell 205 (e.g., by a capacitor 230) may be representative of a programmed state. Other memory architectures that support the techniques described herein may implement different types or arrangements of storage components and associated circuitry (e.g., with or without a selection component).

The architecture 200 may include various arrangements of access lines, such as word lines 210 and digit lines 215. An access line may be a conductive line that is coupled with a memory cell 205, and may be used to perform access operations on the memory cell 205. Word lines 210 may be referred to as row lines, and digit lines 215 may be referred to as column lines or bit lines, among other nomenclature. Memory cells 205 may be positioned at intersections of access lines, and an intersection may be referred to as an address of a memory cell 205.

In some architectures, a word line 210 may be coupled with a gate of a selection component 235 of a memory cell 205, and may be operable to control (e.g., switch, modulate a conductivity of) the selection component 235. A digit line 215 may be operable to couple a memory cell 205 with a sense component 245. In some architectures, a memory cell 205 (e.g., a capacitor 230) may be coupled with a digit line 215 during portions of an access operation. For example, a word line 210 and a selection component 235 of a memory cell 205 may be operable to couple or isolate a capacitor 230 of the memory cell 205 with a digit line 215.

Operations such as reading and writing may be performed on memory cells 205 by activating (e.g., applying a voltage to) access lines such as a word line 210 or a digit line 215. Accessing the memory cells 205 may be controlled through a row decoder 220, or a column decoder 225, or a combination thereof. For example, a row decoder 220 may receive a row address (e.g., from a local memory controller 260) and activate a word line 210 based on a received row address, and a column decoder 225 may receive a column address and activate a digit line 215 based on a received column address. Selecting or deselecting a memory cell 205 may include activating or deactivating a selection component 235 using a word line 210. For example, a capacitor 230 may be isolated from a digit line 215 when the selection component 235 is deactivated, and the capacitor 230 may be coupled with the digit line 215 when the selection component 235 is activated.

A sense component 245 may be operable to detect a state (e.g., a charge) stored by a capacitor 230 of a memory cell 205 and determine a logic state of the memory cell 205 based on the stored state. A sense component 245 may include one or more sense amplifiers to amplify or otherwise convert a signal resulting from accessing the memory cell 205. The sense component 245 may compare a signal detected from the memory cell 205 with a reference 250 (e.g., a reference voltage). The detected logic state of the memory cell 205 may be provided as an output of the sense component 245 (e.g., via an input/output 255), and may indicate the detected logic state to another component of a memory system 110 that implements the architecture 200.

The local memory controller 260 may control the accessing of memory cells 205 through the various components (e.g., a row decoder 220, a column decoder 225, a sense component 245), and may be an example of or otherwise included in a local controller 150, or a memory system controller 140, or both. In some examples, one or more of a row decoder 220, a column decoder 225, and a sense component 245 may be co-located with or included in the local memory controller 260. The local memory controller 260 may be operable to receive commands or data from one or more different controllers (e.g., a host system controller 120, a memory system controller 140), translate the commands or the data into information that can be used by the architecture 200, initiate or control one or more operations of the architecture 200, and communicate data from the architecture 200 to a host (e.g., a host system 105) based on performing the one or more operations.

The local memory controller 260 may be operable to perform one or more access operations on one or more memory cells 205 of the architecture 200. Examples of an access operation may include a write operation, a read operation, a refresh operation, a precharge operation, or an activate operation, among others. In some examples, an access operation may be performed by or otherwise coordinated by the local memory controller 260 in response to one or more access commands (e.g., from a host system 105). The local memory controller 260 may be operable to perform other access operations not listed here or other operations related to the operating of the architecture 200 that are not directly related to accessing the memory cells 205.

In some cases, the architecture 200 may also include antifuse circuitry including multiple antifuses associated with the array of memory cells 205. The antifuses may be activated to alter the circuitry of the architecture 200. For example, activating one or more antifuses may be associated with a repair procedure (e.g., to repair a faulty row of memory cells 205 or a faulty column of memory cells 205) or with tuning a voltage level or current level associated with operation of the architecture 200. However, some antifuse activation techniques may be relatively slow or may cause damage to other components. Accordingly, aspects described herein may provide techniques for reducing durations associated with activating antifuses without exceeding device constraints (e.g., voltage level constraints, temperature constraints). For example, the architecture 200 may include one or more local voltage regulators to compensate for voltage drops across respective sets of antifuses, thus increasing a quantity of antifuses that may be concurrently activated. As such, applying one or more techniques described herein may support high volume manufacturing of memory devices and improved accuracy of testing and evaluation procedures, among other benefits.

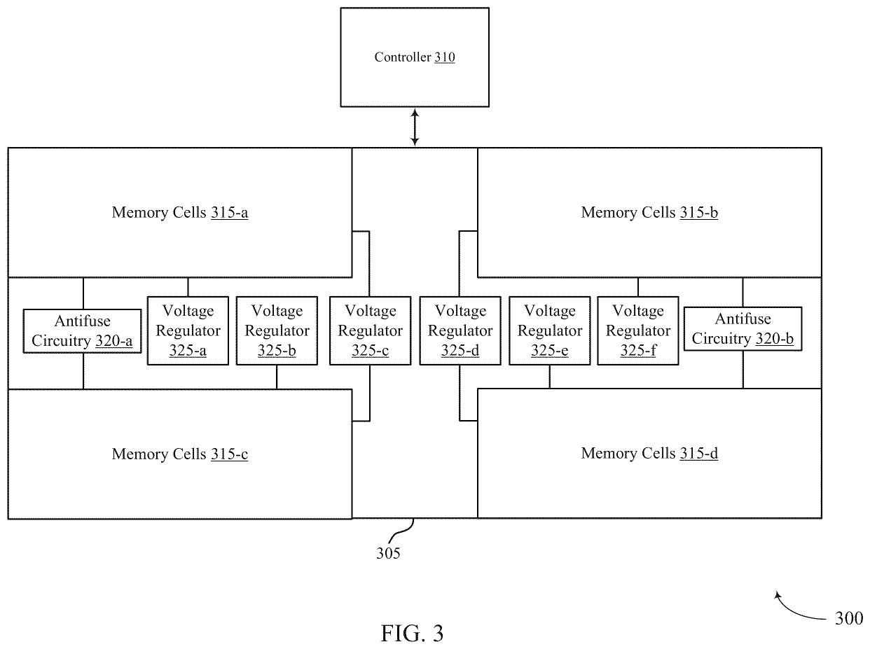

FIG. 3 shows an example of a system 300 (e.g., a memory system, a semiconductor component, a semiconductor die) that supports voltage regulation for memory array test procedures in accordance with examples as disclosed herein. The system 300 may be an example of or include a memory system 110, a memory device 145, or a host system 105. The system 300 may include a memory array 305 (e.g., a DRAM), which may be an example of or include a memory array 155 or an architecture 200. The system 300 may also include a controller 310 coupled with the memory array 305, which may be an example of or include an external controller (e.g., a host system controller 120), an internal controller (e.g., a memory system controller 140, a local controller 150, a local memory controller 260), or some other controller. The controller 310 may control aspects of the memory array 305 including operations associated with memory cells 315, antifuse circuitry 320, voltage regulators 325, or any combination thereof. The memory array 305 may include multiple voltage regulators 325, which may provide for increased efficiency for some test procedures (e.g., as part of device manufacturing).

In some cases, a memory array 305 may include antifuse circuitry 320 (e.g., antifuse elements, one or more arrays of antifuses), which may be used to alter (e.g., blow, activate) internal circuitry. For example, the memory array 305 may activate respective antifuses of the antifuse circuitry 320 to modify a circuit (e.g., via activation or blowing of redundancy fuses, via activation of redundant circuitry). The activation of the antifuses may repair faulty rows of memory cells 315, or repair faulty columns of memory cells 315, or may otherwise modify the circuitry of the memory array 305. Activating an antifuse (e.g., blowing an antifuse) may, in some cases, include applying a voltage (e.g., an activation voltage, a blow voltage) across the antifuse. Each antifuse may be associated with a respective threshold voltage level, which may be a same threshold voltage level as other antifuses or different voltage levels compared to other antifuses. The threshold voltage level may be associated with a voltage level that, if satisfied (e.g., by an applied voltage or a maintained voltage), may activate a corresponding antifuse. For instance, if the applied voltage across the antifuse exceeds a threshold voltage level for the antifuse, the antifuse may transition from a resistive state (e.g., an open circuit state) to a conductive state (e.g., a closed circuit state).

Additionally, or alternatively, the antifuse circuitry 320 may be used to activate a test mode (e.g., internal test modes of the memory array 305, or change a functionality of a test mode) from a set of one or more test modes. The one or more test modes may be associated with different test voltage levels (e.g., 1.0 V, 1.1 V, 1.2 V, and so on), and may be activated based on a quantity (e.g., or configuration) of antifuses that are activated in the antifuse circuitry 320. As a non-limiting example, a state of an antifuse may be represented by a “0” or a “1,” where a “0” may indicate that the antifuse is not activated and a “1” may indicate that the antifuse is activated. In such an example, a first test voltage level may correspond to a first state of one or more antifuses (e.g., 000), a second test voltage level may correspond to a second state (e.g., 001) of the one or more antifuses, a third test voltage level may correspond to a third state (e.g., 010) of the one or more antifuses, and so on.

The memory array 305 may include multiple groups of memory cells 315 (e.g., bytes of memory cells 315), which may include or be examples of groups of memory cells 205. Although the memory array 305 is shown to include four groups of memory cells 315 (e.g., memory cells 315-a, memory cells 315-b, memory cells 315-c, and memory cells 315-d), it is to be understood that a memory array 305 may include any quantity of groups of memory cells 315 arranged in any pattern or order. In some cases, the memory array 305 may include antifuse circuitry 320 between respective groups of memory cells 315. For example, the antifuse circuitry 320 may be distributed horizontally (e.g., in a horizontal spine), vertically (e.g., in a vertical spine), or elsewhere throughout the memory array 305. In some cases, a data transport (e.g., fuse data transport) may occur via components distributed in a vertical direction (e.g., through a vertical spine) of the memory array 305.

The various memory cells 315 may also be associated with different regions of the memory array 305. As a non-limiting example, the memory array 305 may include an upper-left column region (e.g., COL_UP_LE, a column region of the memory cells 315-a), an upper-right column region (e.g., COL_UP_RI, a column region of the memory cells 315-b), a lower-left column region (e.g., COL_DN_LE, a column region of the memory cells 315-c), a lower-right column region (e.g., COL_DN_RI, a column region of the memory cells 315-d), a left row region (e.g., ROW_LE, a row region of the memory cells 315-a and the memory cells 315-c), and a right row region (e.g., ROW_RI, a row region of the memory cells 315-b and the memory cells 315-d). The memory array 305 may also support other configurations including any quantity of regions of memory cells 315 (e.g., upper row regions and lower row regions). In some cases, each region may share at least a portion of antifuse circuitry 320 or may be associated with respective antifuse circuitries 320.

In some cases, the antifuse circuitry 320 may include a column antifuse-array (e.g., including a first quantity of fuse-pairs), a row antifuse-array (e.g., including a second quantity of fuse-pairs), a design for test (DFT) antifuse-array (e.g., including a third quantity of fuse-pairs), a column flip-flop (FF) chain (e.g., including a first quantity of FF circuits) and a first SRAM-array (e.g., associated with a first quantity of bits), a row FF chain (e.g., including a second quantity of FF circuits) and a second SRAM-array (e.g., associated with a second quantity of bits), a distributed DFT FF chain (e.g., including a third quantity of FF circuits). In some cases, the various FF chains may be associated with fuse data transport (e.g., through a vertical spine of the memory array 305). As an example, the antifuse circuitry 320-a may be associated with the memory cells 315-a and the memory cells 315-c, and the antifuse circuitry 320-b may be associated with (e.g., coupled with) the memory cells 315-b and the memory cells 315-d.

As part of a manufacturing process (e.g., during a new product introduction phase), a system 300 may undergo one or more test procedures or evaluations (e.g., to verify proper functionality of the system 300, to improve or calibrate a performance of the system 300). The one or more test procedures may include activation of antifuses. In some cases, antifuses may be activated for various operations such as to activate test modes, to perform row repair or column repair, to fine-tune voltage levels or current levels to a target value, to modify internal circuits to improve a performance of the system 300, among other examples.

In some cases, antifuses may be activated sequentially (e.g., activating one antifuse at a time). However, sequential activation may consume a relatively long duration (e.g., a relatively long test time) and may not be adequate for testing procedures in some manufacturing processes (e.g., high volume manufacturing). Thus, a system 300 may activate multiple antifuses in parallel (e.g., multiple antifuses at a time) to reduce test time durations. In some cases, activating multiple antifuses in parallel may include concurrently applying an activation voltage across the multiple antifuses. However, the activation voltage may drop (e.g., drop below an activation voltage threshold) across the antifuses based on the parallel application of the activation voltage such that at least some of the antifuses may not be activated (e.g., the voltage may not be sufficient to blow the antifuse). Such voltage drops may lead to a failure to activate one or more antifuses (e.g., unblown fuses). Accordingly, an activation voltage may be increased to compensate for the voltage drop, but increasing the activation voltage may cause damage to other components, may exceed device constraints (e.g., temperature constraints, voltage constraints, current constraints), and/or may lead to inadvertent activation of other antifuses (e.g., misblown antifuses). Thus, a quantity of antifuses that may be activated in parallel may be limited (e.g., limited to two antifuses per region of the memory array 305) based on the voltage drop effects and other device constraints.

In some cases, activating multiple antifuses (e.g., two antifuses) in parallel may decrease test times (e.g., compared to sequential activation) but may also be associated with reduced activation efficiency. Accordingly, a system 300 may perform multiple applications of the activation voltage (e.g., multiple activation attempts) to a set of antifuses. For example, multiple antifuses may be activated based on three or more activation attempts. Thus, enhancements to parallel activation of antifuses that enable a system 300 to activate an increased quantity of antifuses and to otherwise improve efficiency in antifuse activation procedures may be beneficial.

In accordance with techniques described herein, a system 300 may include multiple voltage regulators 325 to enhance parallel activation of antifuses of the antifuse circuitry 320. The multiple voltage regulators 325 may be at any location throughout the system 300. In some examples, the memory array 305 may include at least one voltage regulator 325 associated with each region of memory cells 315 (e.g., a local set of one or more voltage regulators per region of memory cells 315). For example, the voltage regulator 325-a may be associated with a first region of memory cells 315 (e.g., a column region of the memory cells 315-a), the voltage regulator 325-b may be associated with a second region of memory cells 315 (e.g., a column region of the memory cells 315-c), the voltage regulator 325-c may be associated with a third region of memory cells 315 (e.g., a row region of the memory cells 315-a and the memory cells 315-c), the voltage regulator 325-d may be associated with a fourth region of memory cells 315 (e.g., a row region of the memory cells 315-b and the memory cells 315-d), the voltage regulator 325-e may be associated with a fifth region of memory cells 315 (e.g., a column region of the memory cells 315-d), and the voltage regulator 325-f may be associated with a sixth region of memory cells 315 (e.g., a column region of the memory cells 315-b). Although example voltage regulators 325-a through 325-f are shown, the memory array 305 may include any quantity of voltage regulators 325 associated with any configuration of regions of memory cells 315.

In some examples, each voltage regulator 325 may compensate for voltage drop effects across a set of antifuses by maintaining an activation voltage level across the antifuse circuitry 320 (e.g., across respective antifuse circuitries 320, thereby increasing antifuse activation efficiency). The voltage regulator 325 may be a capacitor, a voltage generator, or some other component that is capable of maintaining or adding to an applied voltage level. Based on using the voltage regulator 325, the activation voltage may exceed a respective threshold voltage level for each antifuse of the set of antifuses and may activate the set of antifuses. Accordingly, the multiple voltage regulators 325 (e.g., local voltage regulators) may enable a system 300 to increase a quantity of concurrent antifuse activations (e.g., per region) and further reduce a duration associated with some testing procedures. For instance, instead of limiting antifuse activations to two antifuses per region, the multiple voltage regulators 325 may support antifuse activations of three or more antifuses per region.

Moreover, based on the increased efficiency of antifuse activation, the system 300 may reduce a quantity of activation attempts that are performed to activate each of the antifuses (e.g., instead of three activation attempts, the system 300 may activate the corresponding antifuses in two attempts or less), which may further reduce test time. In some examples, the multiple voltage regulators 325 may be examples of or include voltage generators, capacitors, or both. The multiple voltage regulators 325 may also be reused as part of other generator circuitry of the system 300. In some examples, using capacitors as the multiple voltage regulators 325 may be associated with reduced area overhead. Although the multiple voltage regulators 325 are shown as being indirectly coupled with respective antifuse circuitries 320, the multiple voltage regulators 325 may, additionally, or alternatively, be directly coupled with respective antifuse circuitries 320.

In some examples, the system 300 may be configured to perform one or more operations, processes, techniques, or other aspects described herein. For example, the memory array 305 (e.g., including memory cells 315, multiple voltage regulators 325, antifuse circuitry 320, or other internal components) may be coupled with the controller 310, which may be operable to cause the system 300 to perform one or more techniques described herein. Although, the controller 310 is shown as being external to the memory array 305 in FIG. 3, the controller 310 may be internal to the memory array 305, or may be integrated with other components of a memory array 305. Additionally, or alternatively, the memory array 305 may be otherwise configured (e.g., preconfigured, programmed) to perform one or more techniques described herein. For instance, the memory array 305 may be configured based on bandgap circuitry coupled with or included in the memory array 305 (e.g., based on voltages or currents in the bandgap circuitry which may be generated from one or more voltage regulators 325).

In some examples, the system 300 (e.g., the controller 310) may be configured to apply an activation voltage to antifuse circuitry 320 for a region of memory cells 315 in the memory array 305. Additionally, or alternatively, the activation voltage may be applied by an external device, system, or actor during manufacture of a memory device that includes the system 300. In some examples, the antifuse circuitry 320 may be distributed (e.g., horizontally, vertically) between respective regions of memory cells 315 of the memory array. A respective voltage regulator 325 associated with the region of memory cells 315 may maintain the activation voltage across the antifuse circuitry 320 for the region of memory cells 315. The voltage regulator 325 may include one or more voltage generators, or one or more capacitors, or any combination thereof. The activation voltage may exceed a respective threshold voltage level for each antifuse of a set of antifuses within the antifuse circuitry 320 based on the voltage regulator 325. In some examples, the set of antifuses may include three or more antifuses that are activated based on maintaining the activation voltage using the voltage regulator 325. The system 300 may thus activate the set of antifuses based on maintaining the activation voltage using the voltage regulator 325, where the set of antifuses may transition from a resistive state (e.g., a state that isolates two or more components coupled via an antifuse) to a conductive state (e.g., a state that electrically couples two or more components coupled via an antifuse) based on activating the set of antifuses.

In some examples, at least one antifuse of the antifuse circuitry 320 may fail to activate (e.g., after a first attempt to activate the antifuses, may remain in a resistive state). Accordingly, the system 300 may be configured to apply a second activation voltage (e.g., a second attempt) to the antifuse circuitry 320 based on failing to activate at least one antifuse for the region of memory cells 315. The respective voltage regulator 325 may maintain the second activation voltage across the antifuse circuitry 320, which may exceed a second respective threshold voltage level for the antifuses (e.g., the at least one antifuse that failed to activate) based on the voltage regulator. The second respective threshold voltage may be a same voltage as the threshold voltage of the first attempt or a different voltage (e.g., a higher voltage or a lower voltage) from the threshold voltage of the first attempt. The at least one antifuse may be activated based on maintaining the second activation voltage using the voltage regulator 325.

The activation of antifuses may be based on (e.g., or part of) one or more procedures, such as test procedures (e.g., during an initial test phase of a manufacturing process). For example, activating a test mode of a set of one or more test modes may be based on activating the set of antifuses. The test mode may be associated with a test voltage level, where each test mode of the set of one or more test modes may be associated with a respective test voltage level based on a quantity of antifuses that are activated. Additionally, or alternatively, the system 300 may perform a test procedure for the memory array 305, where activating the set of antifuses may be based on performing the test procedure. For example, the test procedure may include a row repair procedure for a first set of memory cells 315 within a region of memory cells 315, a column repair procedure for a second set of memory cells 315 within the region of memory cells 315, or both.

In some examples, the system 300 may use multiple voltage regulators 325 to concurrently apply activation voltages to respective regions of memory cells 315. For example, the system 300 may apply an activation voltage to first antifuse circuitry 320 (e.g., antifuse circuitry 320-a) for a first region of memory cells 315 and may apply the activation voltage to second antifuse circuitry 320 (e.g., antifuse circuitry 320-b) for a second region of memory cells 315 in the memory array 305 concurrently with applying the activation voltage to the first antifuse circuitry 320. The system 300 may maintain the activation voltage across the first antifuse circuitry 320 using a first voltage regulator 325 associated with the first region of memory cells 315 and may maintain, using a second voltage regulator 325 associated with the second region of memory cells, the activation voltage across the second antifuse circuitry 320 for the second region of memory cells 315. The activation voltage may exceed the respective threshold voltage level for each antifuse of a second set of antifuses within the second antifuse circuitry 320 based on the second voltage regulator 325. The system 300 may activate the second set of antifuses concurrently with activating a first set of antifuses based on maintaining the activation voltage using the second voltage regulator 325.

Accordingly, by applying one or more techniques described herein, the system 300 may be enabled to enhanced parallel activation of antifuses. For example, by using multiple voltage regulators 325, the system 300 may be enabled to activate an increased quantity of antifuses at a time, thus reducing a duration associated with antifuse activation procedures. Further, the multiple voltage regulators 325 may increase activation efficiency of antifuses by successfully activating antifuses in relatively fewer activation attempts. Such advantages may reduce overall testing time of memory devices, thus support high volume manufacturing and increasing efficiency in production of electronic devices.

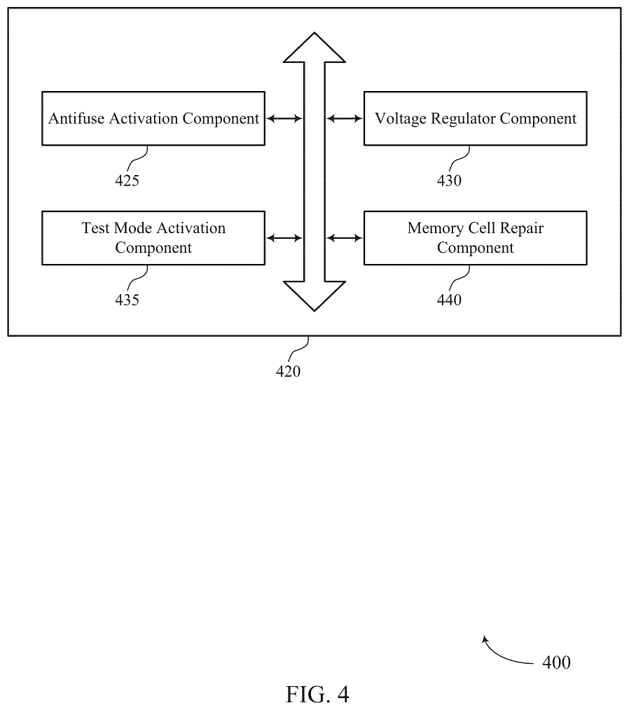

FIG. 4 shows a block diagram 400 of a memory system 420 that supports voltage regulation for memory array test procedures in accordance with examples as disclosed herein. The memory system 420 may be an example of aspects of a memory system as described with reference to FIGS. 1 through 3. The memory system 420, or various components thereof, may be an example of means for performing various aspects of voltage regulation for memory array test procedures as described herein. For example, the memory system 420 may include an antifuse activation component 425, a voltage regulator component 430, a test mode activation component 435, a memory cell repair component 440, or any combination thereof. Each of these components, or components of subcomponents thereof (e.g., one or more processors, one or more memories), may communicate, directly or indirectly, with one another (e.g., via one or more buses).

The antifuse activation component 425 may be configured as or otherwise support a means for applying an activation voltage to antifuse circuitry for a region of memory cells in a memory array. The voltage regulator component 430 may be configured as or otherwise support a means for maintaining, using a voltage regulator associated with the region of memory cells, the activation voltage across the antifuse circuitry for the region of memory cells, the activation voltage exceeding a respective threshold voltage level for each antifuse of a set of antifuses within the antifuse circuitry based at least in part on the voltage regulator. In some examples, the antifuse activation component 425 may be configured as or otherwise support a means for activating the set of antifuses based at least in part on maintaining the activation voltage using the voltage regulator, the set of antifuses transitioning from a resistive state to a conductive state based at least in part on activating the set of antifuses. In some examples, the voltage regulator includes a voltage generator, or a capacitor, or both. In some examples, the set of antifuses includes three or more antifuses that are activated based at least in part on maintaining the activation voltage using the voltage regulator.

In some examples, the antifuse activation component 425 may be configured as or otherwise support a means for applying a second activation voltage to the antifuse circuitry based at least in part on failing to activate at least one antifuse of the antifuse circuitry for the region of memory cells. In some examples, the voltage regulator component 430 may be configured as or otherwise support a means for maintaining, using the voltage regulator, the second activation voltage across the antifuse circuitry, the second activation voltage exceeding a second respective threshold voltage level for the at least one antifuse based at least in part on the voltage regulator, where the at least one antifuse is activated based at least in part on maintaining the second activation voltage using the voltage regulator.

In some examples, the test mode activation component 435 may be configured as or otherwise support a means for activating a test mode of a set of one or more test modes based at least in part on activating the set of antifuses, the test mode associated with a test voltage level, where each test mode of the set of one or more test modes is associated with a respective test voltage level based at least in part on a quantity of antifuses that are activated.

In some examples, the memory cell repair component 440 may be configured as or otherwise support a means for performing a test procedure for the memory array, where activating the set of antifuses is based at least in part on performing the test procedure, the test procedure including a row repair procedure for a first set of memory cells within the region of memory cells, a column repair procedure for a second set of memory cells within the region of memory cells, or both.

In some examples, the antifuse activation component 425 may be configured as or otherwise support a means for applying the activation voltage to second antifuse circuitry for a second region of memory cell in the memory array concurrently with applying the activation voltage to the antifuse circuitry. In some examples, the voltage regulator component 430 may be configured as or otherwise support a means for maintaining, using a second voltage regulator associated with the second region of memory cells, the activation voltage across the second antifuse circuitry for the second region of memory cells, the activation voltage exceeding the respective threshold voltage level for each antifuse of a second set of antifuses within the second antifuse circuitry based at least in part on the second voltage regulator. In some examples, the antifuse activation component 425 may be configured as or otherwise support a means for activating the second set of antifuses concurrently with activating the set of antifuses based at least in part on maintaining the activation voltage using the second voltage regulator, the second set of antifuses transitioning from the resistive state to the conductive state based at least in part on activating the second set of antifuses.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

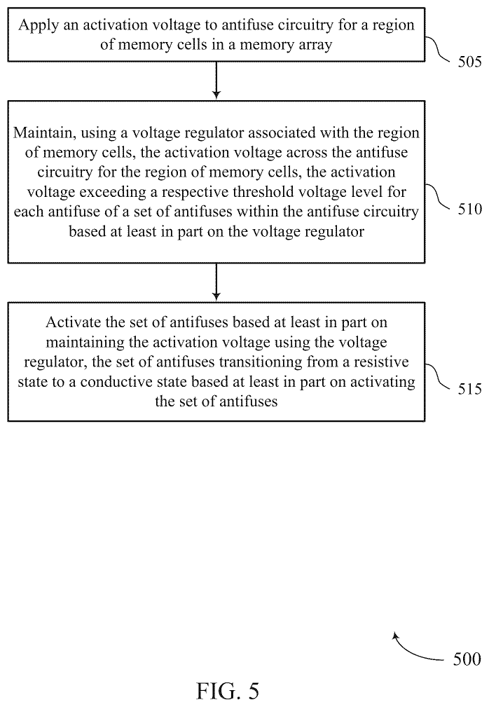

FIG. 5 shows a flowchart illustrating a method 500 that supports voltage regulation for memory array test procedures in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include applying an activation voltage to antifuse circuitry for a region of memory cells in a memory array. In some examples, aspects of the operations of 505 may be performed by an antifuse activation component 425 as described with reference to FIG. 4.

At 510, the method may include maintaining, using a voltage regulator associated with the region of memory cells, the activation voltage across the antifuse circuitry for the region of memory cells, the activation voltage exceeding a respective threshold voltage level for each antifuse of a set of antifuses within the antifuse circuitry based at least in part on the voltage regulator. In some examples, aspects of the operations of 510 may be performed by a voltage regulator component 430 as described with reference to FIG. 4.

At 515, the method may include activating the set of antifuses based at least in part on maintaining the activation voltage using the voltage regulator, the set of antifuses transitioning from a resistive state to a conductive state based at least in part on activating the set of antifuses. In some examples, aspects of the operations of 515 may be performed by an antifuse activation component 425 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for applying an activation voltage to antifuse circuitry (e.g., antifuse circuitry 320) for a region of memory cells in a memory array; maintaining, using a voltage regulator (e.g., a voltage regulators 325) associated with the region of memory cells, the activation voltage across the antifuse circuitry for the region of memory cells, the activation voltage exceeding a respective threshold voltage level for each antifuse of a set of antifuses within the antifuse circuitry based at least in part on the voltage regulator; and activating the set of antifuses based at least in part on maintaining the activation voltage using the voltage regulator, the set of antifuses transitioning from a resistive state to a conductive state based at least in part on activating the set of antifuses.

Aspect 2: The method, apparatus, or non-transitory computer-readable medium of aspect 1, further including operations, features, circuitry, logic, means, or instructions, or any combination thereof for applying a second activation voltage to the antifuse circuitry based at least in part on failing to activate at least one antifuse of the antifuse circuitry for the region of memory cells and maintaining, using the voltage regulator, the second activation voltage across the antifuse circuitry, the second activation voltage exceeding a second respective threshold voltage level for the at least one antifuse based at least in part on the voltage regulator, where the at least one antifuse is activated based at least in part on maintaining the second activation voltage using the voltage regulator.

Aspect 3: The method, apparatus, or non-transitory computer-readable medium of any of aspects 1 through 2, further including operations, features, circuitry, logic, means, or instructions, or any combination thereof for activating a test mode of a set of one or more test modes based at least in part on activating the set of antifuses, the test mode associated with a test voltage level, where each test mode of the set of one or more test modes is associated with a respective test voltage level based at least in part on a quantity of antifuses that are activated.

Aspect 4: The method, apparatus, or non-transitory computer-readable medium of any of aspects 1 through 3, further including operations, features, circuitry, logic, means, or instructions, or any combination thereof for performing a test procedure for the memory array, where activating the set of antifuses is based at least in part on performing the test procedure, the test procedure including a row repair procedure for a first set of memory cells within the region of memory cells, a column repair procedure for a second set of memory cells within the region of memory cells, or both.

Aspect 5: The method, apparatus, or non-transitory computer-readable medium of any of aspects 1 through 4, where the voltage regulator includes a voltage generator, or a capacitor, or both.

Aspect 6: The method, apparatus, or non-transitory computer-readable medium of any of aspects 1 through 5, where the set of antifuses includes three or more antifuses that are activated based at least in part on maintaining the activation voltage using the voltage regulator.

Aspect 7: The method, apparatus, or non-transitory computer-readable medium of any of aspects 1 through 6, further including operations, features, circuitry, logic, means, or instructions, or any combination thereof for applying the activation voltage to second antifuse circuitry for a second region of memory cell in the memory array concurrently with applying the activation voltage to the antifuse circuitry; maintaining, using a second voltage regulator associated with the second region of memory cells, the activation voltage across the second antifuse circuitry for the second region of memory cells, the activation voltage exceeding the respective threshold voltage level for each antifuse of a second set of antifuses within the second antifuse circuitry based at least in part on the second voltage regulator; and activating the second set of antifuses concurrently with activating the set of antifuses based at least in part on maintaining the activation voltage using the second voltage regulator, the second set of antifuses transitioning from the resistive state to the conductive state based at least in part on activating the second set of antifuses.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 8: An apparatus, including: a memory array including a plurality of regions of memory cells; a plurality of voltage regulators coupled with the plurality of regions of memory cells; and a controller coupled with the memory array and the plurality of voltage regulators, where the controller is operable to: apply an activation voltage to antifuse circuitry for a region of memory cells of the memory array; maintain, using a voltage regulator of the plurality of voltage regulators, the activation voltage across the antifuse circuitry for the region of memory cells, the activation voltage exceeding a respective threshold voltage level at each antifuse of a set of antifuses within the antifuse circuitry based at least in part on the voltage regulator; and activate the set of antifuses based at least in part on maintaining the activation voltage using the voltage regulator, the set of antifuses transitioning from a resistive state to a conductive state based at least in part on activating the set of antifuses.

Aspect 9: The apparatus of aspect 8, where the antifuse circuitry is distributed between respective regions of memory cells of the plurality of regions of memory cells of the memory array.

Aspect 10: The apparatus of any of aspects 8 through 9, where the controller is further operable to: apply a second activation voltage to the antifuse circuitry based at least in part on failing to activate at least one antifuse of the antifuse circuitry for the region of memory cells; and maintain, using the voltage regulator, the second activation voltage across the antifuse circuitry, the second activation voltage exceeding a second respective threshold voltage level for the at least one antifuse based at least in part on the voltage regulator, where the at least one antifuse is activated based at least in part on maintaining the second activation voltage using the voltage regulator.

Aspect 11: The apparatus of any of aspects 8 through 10, where the controller is further operable to: activate a test mode of a set of one or more test modes based at least in part on activating the set of antifuses, the test mode associated with a test voltage level, where each test mode of the set of one or more test modes is associated with a respective test voltage level based at least in part on a quantity of antifuses that are activated.

Aspect 12: The apparatus of any of aspects 8 through 11, where the controller is further operable to: perform a test procedure for the memory array, where activating the set of antifuses is based at least in part on the test procedure, the test procedure including a row repair procedure for a first set of memory cells within the region of memory cells, a column repair procedure for a second set of memory cells within the region of memory cells, or both.

Aspect 13: The apparatus of any of aspects 8 through 12, where the voltage regulator includes a voltage generator, or a capacitor, or both.

Aspect 14: The apparatus of any of aspects 8 through 13, where the set of antifuses includes three or more antifuses that are activated based at least in part on maintaining the activation voltage using the voltage regulator.

Aspect 15: The apparatus of any of aspects 8 through 14, where the controller is further operable to: apply the activation voltage to second antifuse circuitry for a second region of memory cell in the memory array concurrently with applying the activation voltage to the antifuse circuitry; maintain, using a second voltage regulator of the plurality of voltage regulators, the activation voltage across the second antifuse circuitry for the second region of memory cells, the activation voltage exceeding the respective threshold voltage level for each antifuse of a second set of antifuses within the second antifuse circuitry based at least in part on the second voltage regulator; and activate the second set of antifuses concurrently with activating the set of antifuses based at least in part on maintaining the activation voltage using the second voltage regulator, the second set of antifuses transitioning from the resistive state to the conductive state based at least in part on activating the second set of antifuses.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processor. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, that can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or a processor.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method, comprising:
applying an activation voltage to antifuse circuitry for a region of memory cells in a memory array;
maintaining, using a voltage regulator associated with the region of memory cells, the activation voltage across the antifuse circuitry for the region of memory cells, the activation voltage exceeding a respective threshold voltage level for each antifuse of a set of antifuses within the antifuse circuitry based at least in part on the voltage regulator; and
activating the set of antifuses based at least in part on maintaining the activation voltage using the voltage regulator, the set of antifuses transitioning from a resistive state to a conductive state based at least in part on activating the set of antifuses.

2. The method of claim 1, further comprising:
applying a second activation voltage to the antifuse circuitry based at least in part on failing to activate at least one antifuse of the antifuse circuitry for the region of memory cells; and
maintaining, using the voltage regulator, the second activation voltage across the antifuse circuitry, the second activation voltage exceeding a second respective threshold voltage level for the at least one antifuse based at least in part on the voltage regulator, wherein the at least one antifuse is activated based at least in part on maintaining the second activation voltage using the voltage regulator.

3. The method of claim 1, further comprising:
activating a test mode of a set of one or more test modes based at least in part on activating the set of antifuses, the test mode associated with a test voltage level, wherein each test mode of the set of one or more test modes is associated with a respective test voltage level based at least in part on a quantity of antifuses that are activated.

4. The method of claim 1, further comprising:
performing a test procedure for the memory array, wherein activating the set of antifuses is based at least in part on performing the test procedure, the test procedure comprising a row repair procedure for a first set of memory cells within the region of memory cells, a column repair procedure for a second set of memory cells within the region of memory cells, or both.

5. The method of claim 1, wherein the voltage regulator comprises a voltage generator, or a capacitor, or both.

6. The method of claim 1, wherein the set of antifuses comprises three or more antifuses that are activated based at least in part on maintaining the activation voltage using the voltage regulator.

7. The method of claim 1, further comprising:
applying the activation voltage to second antifuse circuitry for a second region of memory cells in the memory array concurrently with applying the activation voltage to the antifuse circuitry;
maintaining, using a second voltage regulator associated with the second region of memory cells, the activation voltage across the second antifuse circuitry for the second region of memory cells, the activation voltage exceeding the respective threshold voltage level for each antifuse of a second set of antifuses within the second antifuse circuitry based at least in part on the second voltage regulator; and
activating the second set of antifuses concurrently with activating the set of antifuses based at least in part on maintaining the activation voltage using the second voltage regulator, the second set of antifuses transitioning from the resistive state to the conductive state based at least in part on activating the second set of antifuses.

8. An apparatus, comprising:
a memory array comprising a plurality of regions of memory cells;
a plurality of voltage regulators coupled with the plurality of regions of memory cells; and
a controller coupled with the memory array and the plurality of voltage regulators, wherein the controller is operable to:
apply an activation voltage to antifuse circuitry for a region of memory cells of the memory array;
maintain, using a voltage regulator of the plurality of voltage regulators, the activation voltage across the antifuse circuitry for the region of memory cells, the activation voltage exceeding a respective threshold voltage level at each antifuse of a set of antifuses within the antifuse circuitry based at least in part on the voltage regulator; and
activate the set of antifuses based at least in part on maintaining the activation voltage using the voltage regulator, the set of antifuses transitioning from a resistive state to a conductive state based at least in part on activating the set of antifuses.

9. The apparatus of claim 8, wherein the antifuse circuitry is distributed between respective regions of memory cells of the plurality of regions of memory cells of the memory array.

10. The apparatus of claim 8, wherein the controller is further operable to:
apply a second activation voltage to the antifuse circuitry based at least in part on failing to activate at least one antifuse of the antifuse circuitry for the region of memory cells; and
maintain, using the voltage regulator, the second activation voltage across the antifuse circuitry, the second activation voltage exceeding a second respective threshold voltage level for the at least one antifuse based at least in part on the voltage regulator, wherein the at least one antifuse is activated based at least in part on maintaining the second activation voltage using the voltage regulator.

11. The apparatus of claim 8, wherein the controller is further operable to:
activate a test mode of a set of one or more test modes based at least in part on activating the set of antifuses, the test mode associated with a test voltage level, wherein each test mode of the set of one or more test modes is associated with a respective test voltage level based at least in part on a quantity of antifuses that are activated.

12. The apparatus of claim 8, wherein the controller is further operable to:
perform a test procedure for the memory array, wherein activating the set of antifuses is based at least in part on the test procedure, the test procedure comprising a row repair procedure for a first set of memory cells within the region of memory cells, a column repair procedure for a second set of memory cells within the region of memory cells, or both.

13. The apparatus of claim 8, wherein the voltage regulator comprises a voltage generator, or a capacitor, or both.

14. The apparatus of claim 8, wherein the set of antifuses comprises three or more antifuses that are activated based at least in part on maintaining the activation voltage using the voltage regulator.

15. The apparatus of claim 8, wherein the controller is further operable to:
apply the activation voltage to second antifuse circuitry for a second region of memory cells in the memory array concurrently with applying the activation voltage to the antifuse circuitry;
maintain, using a second voltage regulator of the plurality of voltage regulators, the activation voltage across the second antifuse circuitry for the second region of memory cells, the activation voltage exceeding the respective threshold voltage level for each antifuse of a second set of antifuses within the second antifuse circuitry based at least in part on the second voltage regulator; and
activate the second set of antifuses concurrently with activating the set of antifuses based at least in part on maintaining the activation voltage using the second voltage regulator, the second set of antifuses transitioning from the resistive state to the conductive state based at least in part on activating the second set of antifuses.

16. A non-transitory computer-readable medium storing code, the code comprising instructions executable by one or more processors to:
apply an activation voltage to antifuse circuitry for a region of memory cells in a memory array;
maintain, using a voltage regulator associated with the region of memory cells, the activation voltage across the antifuse circuitry for the region of memory cells, the activation voltage exceeding a respective threshold voltage level for each antifuse of a set of antifuses within the antifuse circuitry based at least in part on the voltage regulator; and
activate the set of antifuses based at least in part on maintaining the activation voltage using the voltage regulator, the set of antifuses transitioning from a resistive state to a conductive state based at least in part on activating the set of antifuses.

17. The non-transitory computer-readable medium of claim 16, wherein the instructions are further executable by the one or more processors to:
apply a second activation voltage to the antifuse circuitry based at least in part on failing to activate at least one antifuse of the antifuse circuitry for the region of memory cells; and
maintain, using the voltage regulator, the second activation voltage across the antifuse circuitry, the second activation voltage exceeding a second respective threshold voltage level for the at least one antifuse based at least in part on the voltage regulator, wherein the at least one antifuse is activated based at least in part on maintaining the second activation voltage using the voltage regulator.

18. The non-transitory computer-readable medium of claim 16, wherein the instructions are further executable by the one or more processors to:
activate a test mode of a set of one or more test modes based at least in part on activating the set of antifuses, the test mode associated with a test voltage level, wherein each test mode of the set of one or more test modes is associated with a respective test voltage level based at least in part on a quantity of antifuses that are activated.

19. The non-transitory computer-readable medium of claim 16, wherein the instructions are further executable by the one or more processors to:
perform a test procedure for the memory array, wherein activating the set of antifuses is based at least in part on performing the test procedure, the test procedure comprising a row repair procedure for a first set of memory cells within the region of memory cells, a column repair procedure for a second set of memory cells within the region of memory cells, or both.

20. The non-transitory computer-readable medium of claim 16, wherein the voltage regulator comprises a voltage generator, or a capacitor, or both.
